(19) United States
(12) Patent Application Publication
(10) Pub. No.: US 2026/0018479 A1
(43) Pub. Date: Jan. 15, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Ching-Wei LIAO, Taipei City (TW); Chih-Hao WENG, New Taipei City (TW); Keun Soo KIM, Hsinchu City (TW)

(73) Assignee: Amkor Technology Singapore Holding Pte. Ltd., Valley Point #12-03 (SG)

(21) Appl. No.: 18/767,868

(22) Filed: Jul. 9, 2024

(51) Int. Cl. H01L 23/31; H01L 21/78; H01L 23/00

(52) U.S. Cl. CPC H01L 23/3185; H01L 21/78; H01L 23/3171; H01L 24/05; H01L 2224/02377; H01L 2224/0401

(57) ABSTRACT

In one example, an electronic device includes an electronic component including a first side, a second side opposite to the first side, a lateral side connecting the first side to the second side, bond pads adjacent to the first side, and a passivation layer over the first side and including openings exposing the bond pads. A redistribution structure is over the passivation layer and the bond pads. The redistribution structure includes a conductive structure coupled to the bond pads and a dielectric structure. The conductive structure includes outward terminals. External interconnects are coupled to the outward terminals and a protection layer covers the lateral side of the electronic component. Other examples and related methods are also disclosed herein.

### CROSS-REFERENCE TO RELATED APPLICATIONS

Not Applicable.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, 2G, 2H, and 2I show cross-sectional views of an example method for manufacturing an example electronic device.

FIG. 3 shows a cross-sectional view of an example electronic device.

FIGS. 4A, 4B, 4C, 4D, 4E, and 4F show cross-sectional views of an example method for manufacturing an example electronic device.

FIG. 5 shows a cross-sectional view of an example electronic device.

FIGS. 6A, 6B, 6C, and 6D show cross-sectional views of an example method for manufacturing an example electronic device.

FIG. 7 shows a cross-sectional view of an example electronic device.

FIGS. 8A, 8B, 8C, and 8D show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements.

### DESCRIPTION

The present description includes, among other features, structures and associated methods that relate to electronic devices that are more resilient to stresses encountered during manufacturing. More particularly, structures and methods are described that improve the reliability of electronic devices that reduce defects associated with manufacturing stress, such as chipping or micro cracks at edges of the electronic devices. In some examples, the structures and methods are useful for wafer-level chip scale packages (WLCSP's), which is a technology where electronic devices are packaged at wafer level as opposed to technologies where the individual electronic devices are assembled into packaged units after they are separated from the wafer. WLCSP's are among the smallest packaged electronic devices available with their size being essentially the size of the semiconductor die or chip that forms the base substrate for the electronic devices. WLCSP's typically use redistribution structures that provide communication with the electronic device in fan-in or fan-out configurations and that provide communication with next levels of assembly (e.g., printed circuit boards) with conductive bumps connected to the redistribution structures. WLCSP's have several advantages in addition to their small size, including low inductance and cost effectiveness.

In the past, WLCSP's have been susceptible to stresses and damage during manufacturing because the edges and corners of semiconductor die are exposed and not protected, which has resulted in micro-cracks, chipping, and other stress related damage. These defects detrimentally impact the yield, quality, and reliability of the WLCSP's. Accordingly, structures and methods are described that provide protective structures along various surfaces of electronic devices during wafer fabrication. In some examples, the protective structures can comprise ceramics, metals, organic or inorganic dielectrics, or combinations thereof. It was found through experimentation that the protective structures as described hereinafter reduce the occurrence of micro-cracks, chipping and other defects thereby improving yield, quality, and reliability. In addition, it was found that the protective structures do not result in other defects, such as wafer warpage.

In an example, an electronic device includes an electronic component including a first side, a second side opposite to the first side, a lateral side connecting the first side to the second side, bond pads adjacent to the first side, and a passivation layer over the first side and including openings exposing the bond pads. A redistribution structure is over the passivation layer and the bond pads and includes a conductive structure and a dielectric structure. The conductive structure is coupled to the bond pads and includes outward terminals. External interconnects are coupled to the outward terminals and a protection layer covers the lateral side of the electronic component.

In an example, an electronic device includes an electronic component including a first side, a second side opposite to the first side, a lateral side connecting the first side to the second side, bond pads adjacent to the first side, and a passivation layer over the first side and comprising openings exposing the bond pads. A redistribution structure is over the passivation layer and the bond pads and includes a conductive structure, which is coupled to the bond pads an includes outward terminals, a dielectric structure, and a sidewall inset from the lateral side of the electronic component to expose an upper edge portion of the electronic component at the first side. External interconnects are coupled to the outward terminals. A protection layer covering the lateral side and the upper edge portion of the electronic component and the sidewall of the redistribution structure.

In an example, a method of manufacturing an electronic device includes providing an electronic component including a first side, a second side opposite to the first side, a lateral side connecting the first side to the second side, bond pads adjacent to the first side, and a passivation layer over the first side and comprising openings exposing the bond pad. The method includes providing a redistribution structure over the passivation layer and the bond pads and includes a conductive structure and a dielectric structure. The conductive structure is coupled to the bond pads and includes outward terminals. The method includes providing external interconnects coupled to the outward terminals. The method includes providing a protection layer covering the lateral side of the electronic component.

Other examples are included in the present disclosure. Such examples may be found in the figures, in the claims, or in the description of the present disclosure.

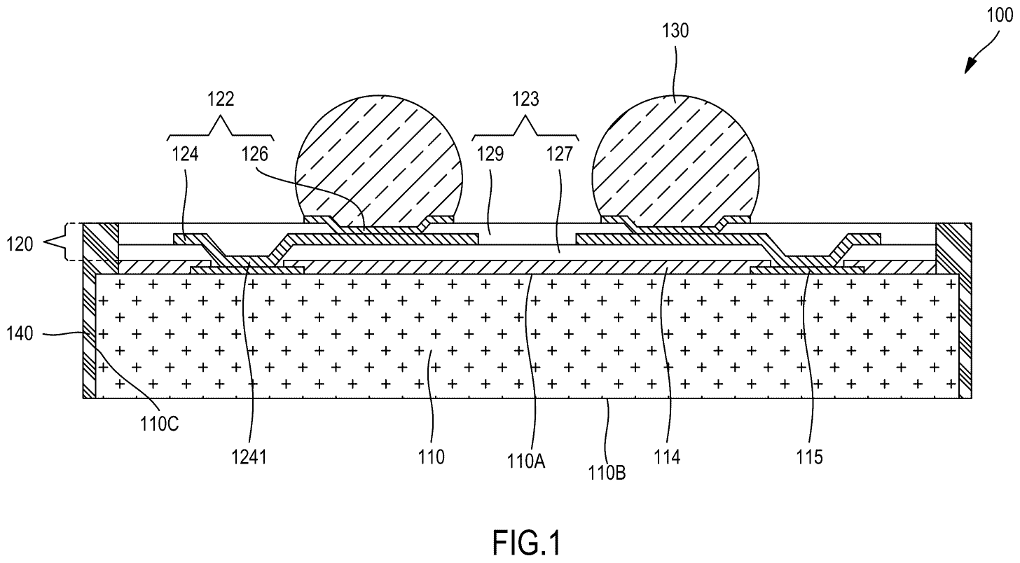

FIG. 1 shows a cross-sectional view of an example electronic device 100. In the example shown in FIG. 1, electronic device 100 can comprise electronic component 110, redistribution structure (RDS) 120, external interconnects 130, and protection layer 140. Electronic device 100 is an example of a WLCSP. Protection layer 140 can also comprise or be referred to as a protective structure.

Electronic component 110 can comprise passivation layer 114 and bond pads 115 adjacent to or over a first side 110A of electronic component 110. Electronic component 110 further comprises a second side 110B opposite to first side 110A and a lateral side 110C connecting first side 110A to second side 110B. In some examples, redistribution structure 120 can comprise conductive structure 122 and dielectric structure 123 over passivation layer 114 and bond pads 115. In some examples, conductive structure 122 can comprise inner conductive pattern(s) 124 and outward terminals 126. Inner conductive pattern 124 can comprise inward terminals 1241 coupled to bond pads 115. Dielectric structure 123 can comprise inner dielectric material 127 and outer dielectric material 129. In some examples, outward terminals 126 are coupled to external interconnects 130. In some examples, redistribution structure 120 comprises a sidewall that is inset from lateral side 110C of electronic component 110 to expose an edge portion 110AA of electronic component 110 at first side 110A.

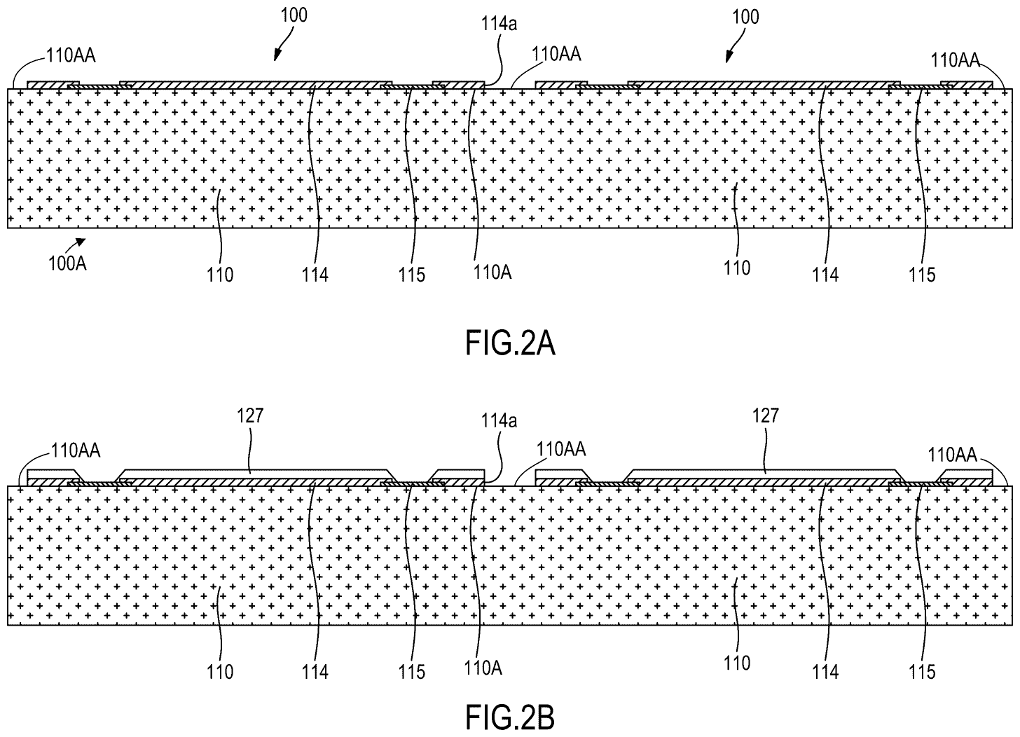

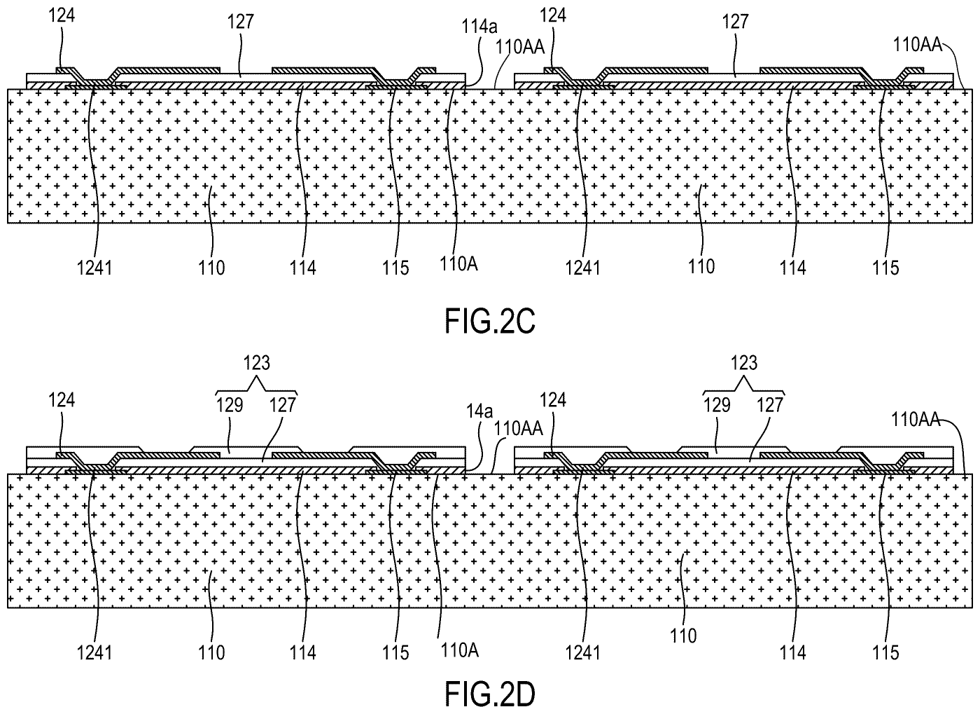

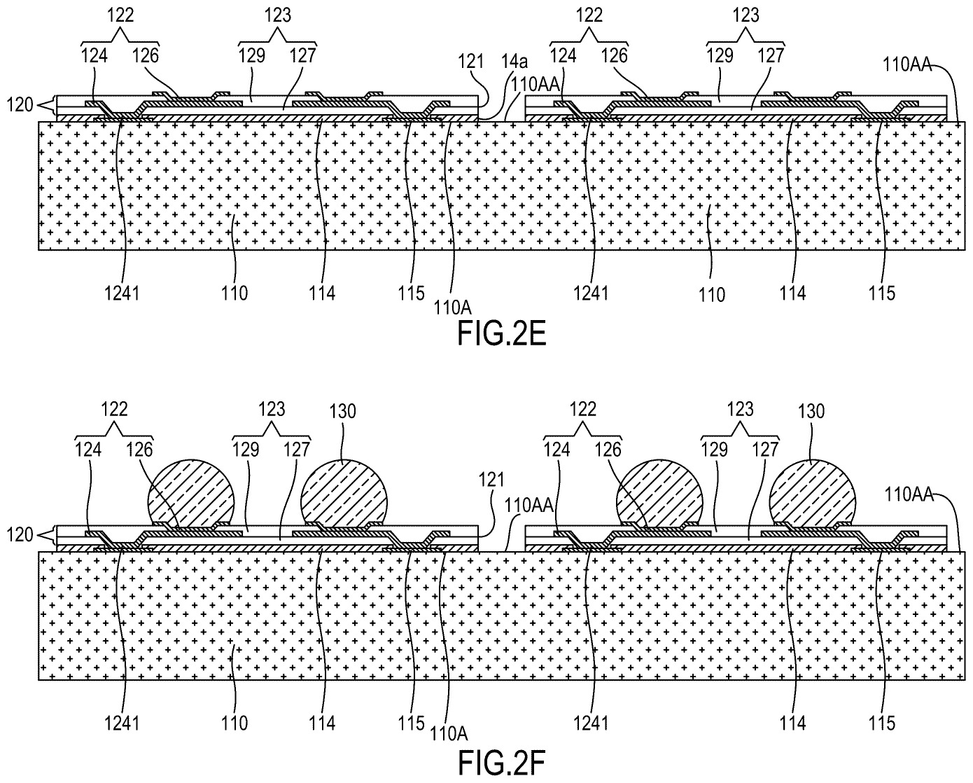

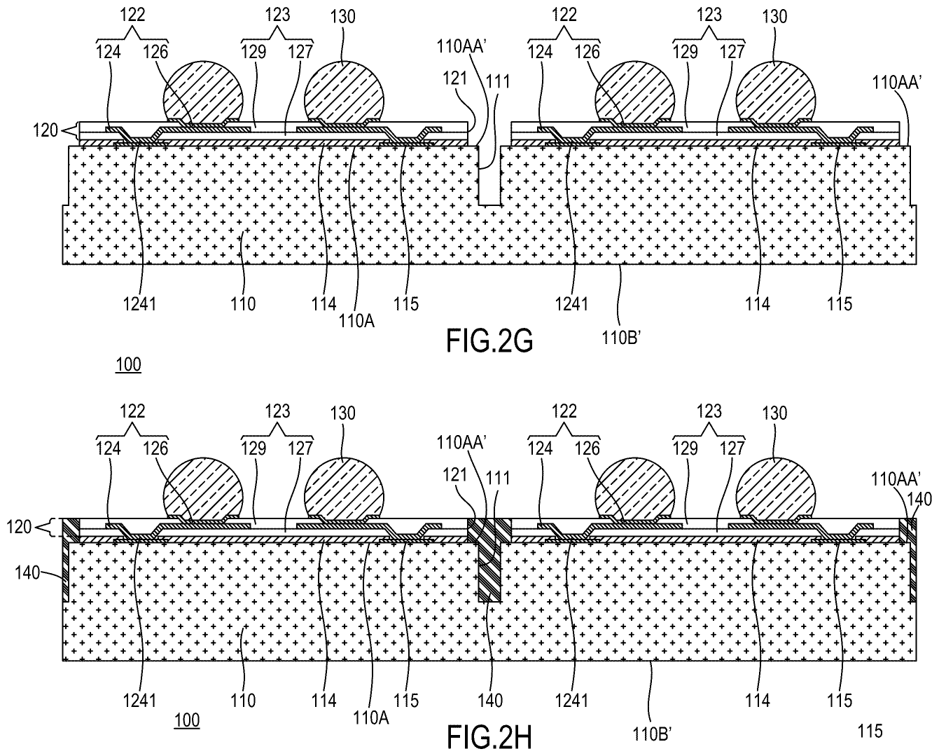

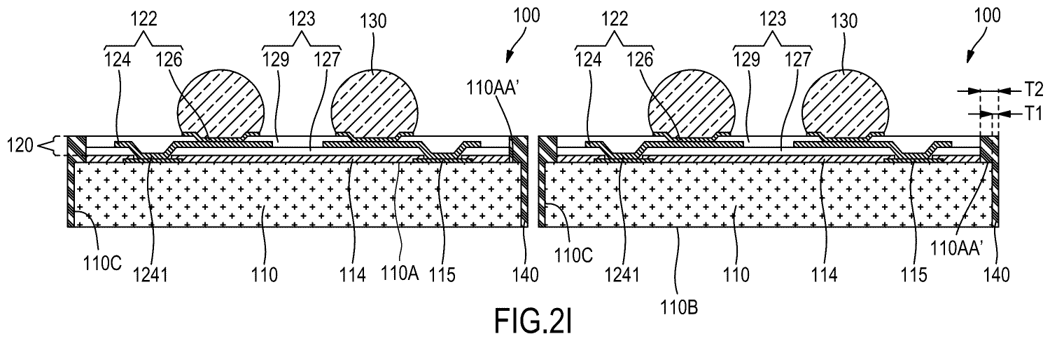

FIGS. 2A, 2B, 2C, 2D, 2E, 2F, 2G, 2H, and 2I show cross-sectional views of an example method for manufacturing an electronic device, such as electronic device 100.

FIG. 2A shows a cross-sectional view of electronic device 100 at an early stage of manufacture. In the example shown in FIG. 2A, electronic device 100 can be provided in wafer form including a plurality of electronic devices 100 each comprising one of electronic components 110. In some examples, a plurality of electronic components 110 are provided within or as part of a semiconductor substrate 100A and additional features or elements are provided or added to the plurality of electronic components 110 before separating semiconductor substrate 100A into individual electronic devices 100. Semiconductor substrate 100A comprises a top side, which defines first sides 110A of electronic components 110 and a lower side opposite to the top side, which may be further processed to define second sides 110B of electronic components 110. Semiconductor substrate 100A can also comprise or be referred to as a semiconductor wafer or work piece.

In some examples, electronic components 110 comprise a semiconductor material including silicon (Si), III-V semiconductor materials, IV-IV semiconductor materials, or combinations thereof. In some examples, electronic components 110 can comprise passive electronic circuit elements or active electronic circuit elements such as transistors proximate to first side 110A, which can also comprise or be referred to as a component active side of electronic components 110.

Electronic components 110 can comprise bond pads 115 and passivation layer 114 provided on first side 110A. Bond pads 115 can be spaced apart from each other in row or column directions. In some examples, bond pads 115 can comprise or be referred to as terminals, component terminals, contacts, or pads. For example, bond pads 115 can be input/output terminals of electronic components 110 configured for providing signals to and from electronic component 110. Bond pads 115 can be electrically connected to electronic circuits element included in electronic component 110. Bond pads 115 can comprise one or more layers of electrically conductive materials such as, for example, aluminum (AI), copper (Cu), an aluminum alloy, or a copper alloy. In some examples, bond pads 115 can be provided on electronic components 110 through a plating or deposition process. In some examples, the deposited materials can be patterned using photolithographic techniques to provide bonds pads 115 in a predetermined pattern on first side 110A. In some examples, the thicknesses of bond pads 115 can range from approximately 0.05 microns (μm) to approximately 10 μm. Bond pads 115 can serve as electrical contacts for providing electrical signals to the electrical circuit elements in electronic components 110.

Passivation layer 114 of electronic components 110 can be over and/or in contact with first side 110A of electronic components 110 and the sidewalls of bond pads 115. In some examples, passivation layer 114 can be in contact with and partially overlap portions of the top sides of bond pads 115. In some examples, passivation layer 114 comprises one or more electrically insulating materials, such as an inorganic material including silicon oxide, silicon nitride, or combinations thereof. Example process techniques for forming passivation layer 114 includes thermal oxidation, chemical vapor deposition (CVD), physical vapor deposition (PVD), atomic layer deposition (ALD), low pressure chemical vapor deposition (LPCVD), plasma enhanced chemical vapor deposition (PECVD), or combinations thereof.

Passivation layer 114 can be provided to cover first side 110A of electronic components 110 and then patterned to expose a portions bond pads 115 and portions 110AA of first side 110A. For example, passivation layer 114 can be patterned using photolithographic techniques. In some examples, passivation layer 114 can be approximately rectangular in shape in a top plan view. in some examples, portions of passivation layer 114 can be spaced apart from each other in a row or column direction over first side 110A of electronic components 110. For example, passivation layer 114 can expose portions 110AA of first side 110A that correspond to singulation lines for separating electronic devices 100 from the semiconductor wafer into individual electronic devices. Portions 110AA of first side 110A of electronic components 110 can be exposed in a square or rectangular ring shape surrounding the active area of electronic components 110 in a top plan view. Due to a separation distance a space between passivation layer 114 and the adjacent passivation layer 114, a cavity 114a can be provided by the sidewalls of passivation layer 114 and portions 110AA of first side 110A. 114a. In the present example, the sidewalls of opposing passivation layers 114 are exposed from cavities 114a. In some examples, the thickness of passivation layer 114 can range from approximately 0.05 μm to approximately 20 μm. The width of cavity 114a can correspond to a separation distance between neighboring passivation layers 114. The location of cavity 114a can correspond to (e.g., vertically overlap) singulations streets between adjacent electronic components 110. In some examples, the width of cavity 114a can range from approximately 10 μm to approximately 300 μm and can depend on the type of singulation process used to separate electronic devices 100 into individual electronic devices. For example, sawing techniques typically require wider singulation lines to accommodate a saw blade and plasma singulation techniques typically can use narrower singulation lines. In the present example, the upper side of passivation layer 114 and the upper side of bond pads 115 are over first side 110A of electronic components 110. Passivation layer 114 can protect the component active side of electronic components 110.

In some examples, electronic components 110 can comprise or be referred to as die, chips, packages, or passives. In some examples, the overall thickness of electronic components 110 can range from approximately 10 μm to approximately 1650 μm.

FIG. 2B shows a cross-sectional view of electronic device 100 at a later stage of manufacture. In the example shown in FIG. 2B, inner dielectric material 127 can be provided to cover passivation layer 114 of electronic components 110. In some examples, inner dielectric material 127 can be referred to as a buildup dielectric layer or insulator. inner dielectric material 127 can comprise an electrically insulating material, an organic material such as, for example, a polymer, polyimide (PI), benzocyclobutene (BCB), polybenzoxazole (PBO), bismaleimide triazine (BT), a molding material, a phenolic resin, an epoxy, silicone, or an acrylate polymer. Examples of processes for forming Inner dielectric material 127 can comprise using spin coating, spray coating, printing, metal organic chemical vapor deposition (MOCVD), PVD, CVD, ALD, LPCVD, PECVD, sheet lamination, evaporation, or combinations thereof.

After inner dielectric material 127 is provided to cover the upper side of passivation layer 114, portions 110AA of first side 110A of electronic components 110 exposed through passivation layer 114, and the upper side of bond pads 115, openings can be provided to expose portions 110AA of first side 110A and the upper side of bond pads 115. For example, the openings of inner dielectric material 127 can provide a mask pattern on the upper side of inner dielectric material 127, and then remove exposed inner dielectric material 127 through etching. In this way inner dielectric material 127 comprises apertures or openings exposing bond pads 115 and portions 110AA of first side 110A. Inner dielectric material 127 can be in contact with the upper side of passivation layer 114. In some examples, inner dielectric material 127 can overlap portions of passivation layer 114 and contact portions of the tops sides of bond pads 115. In some examples, the sidewalls of inner dielectric material 127 can be coplanar with the sidewalls of passivation layer 114. In some examples, the thickness of inner dielectric material 127 can range from approximately 1 μm to approximately 30 μm. In some examples, inner dielectric material 127 can be used to electrically isolate elements in redistribution structure 120.

FIG. 2C shows a cross-sectional view of electronic device 100 at a later stage of manufacture. In the example shown in FIG. 2C, inner conductive patterns 124 can be provided to cover bond pads 115 of electronic components 110 exposed from openings in inner dielectric material 127.

Inner conductive patterns 124 can be provided to have multiple pattern portions on the upper side of inner dielectric material 127 and the upper side of bond pads 115. In some examples, each of inner conductive patterns 124 can be in contact with and be electrically connected to bond pads 115. In some examples, inner conductive patterns 124 in contact with bond pads 115 can extend to overlap portions of the upper side of inner dielectric material 127. In some examples, inner conductive patterns 124 can comprise or be referred to as traces, pads, vias, conductive paths, wiring patterns, or circuit patterns. Inner conductive pattern 124 can comprise inward terminals 1241, which are in contact with bond pads 115 within the openings of inner dielectric material 127. Inward terminals 1241 can be part of inner conductive pattern 124. Inward terminals 1241 can comprise or be referred to as pads, lands, or under-bump-metallurgies (UBMs).

In some examples, Inner conductive pattern 124 can comprise one or more layers or alloys of electrically conductive material such as, for example, a metal, Cu, Al, gold (Au), nickel (Ni), Cu alloys, Al alloys, Au alloys, Ni alloys, tungsten titanium alloy (TiW), Titanium (Ti), or combinations thereof. Examples processes for forming inner conductive patterns 124 include PVD (e.g., sputtering), CVD, ALD, PECVD, electroless plating, electrolytic plating, or combinations thereof. The thickness of inner conductive pattern s124 can range from approximately 1 μm to approximately 30 μm. After formation, the material can be patterned using photolithographic techniques to provide inner conductive patterns 124.

FIG. 2D shows a cross-sectional view of electronic device 100 at a later stage of manufacture. In the example shown in FIG. 2D, outer dielectric material 129 can be provided to cover inner dielectric material 127 of electronic components 110.

In some examples, outer dielectric material 129 can be in contact with the upper side of inner dielectric material 127 and the upper side of inner conductive pattern 124. The outer dielectric material 129 can be provided to cover the upper side of inner dielectric material 127 and the upper sides of inner conductive patterns 124 exposed from openings in inner dielectric material 127. Outer dielectric material 129 can have openings exposing portions of inner conductive patterns 124. In some examples, the sidewalls of outer dielectric material 129 can be coplanar with the sidewalls of inner dielectric material 127. Outer dielectric material 129 can have corresponding elements, features, materials, or manufacturing methods similar to those of inner dielectric material 127.

FIG. 2E shows a cross-sectional view of electronic device 100 at a later stage of manufacture. In the example shown in FIG. 2E, outward terminals 126 can be provided to cover inner conductive patterns 124 exposed through openings in outer dielectric material 129.

Outward terminals 126 can be provided to have multiple patterns over inner conductive patterns 124. Each of outward terminals 126 can be in contact with and be electrically connected to inner conductive patterns 124. Outward terminals 126 in contact with inner conductive patterns 124 can be in contact with some areas of outer dielectric material 129 adjacent to inner conductive pattern 124. Outward terminals 126 can comprise or be referred to as two-step pads, pads or lands. Outward terminals 126 can have corresponding elements, features, materials, or manufacturing methods similar to those of inner conductive pattern 124.

After providing outward terminals 126, redistribution structure 120 can be completed. Redistribution structure 120 can comprise dielectric structure 123 and conductive structure 122. Dielectric structure 123 can comprise outer dielectric material 129 and inner dielectric material 127. Conductive structure 122 can comprise inner conductive patterns 124 and outward terminals 126. Conductive structure 122 can comprise one or more conductive layers defining signal distribution elements. Dielectric structure 123 can comprise one or more layers interleaved between the respective layers of conductive structure 122.

In some examples, dielectric structure 123 can comprise one or more layers between outer dielectric material 129 and inner dielectric material 127. In some examples, conductive structure 122 can comprise one or more layers between inner conductive pattern 124 and outward terminals 126. One or more layers or elements of conductive structure 122 can be interleaved with dielectric structure 123. In some examples, redistribution structure 120 can comprise or be referred to as an RDL substrate, a buildup substrate, a coreless substrate, or a fine-pitch substrate. Redistribution structure 120 can be located above passivation layer 114. In some examples, the sidewalls of passivation layer 114 and the sidewalls of redistribution structure 120 can be coplanar with each other. Redistribution structure 120 can be spaced apart from adjacent redistribution structure 120 and can comprise cavity 121 extending from the upper side of redistribution structure 120 to portions 110AA of first side 110A of electronic components 110. In some examples, cavity 114a of passivation layer 114 can be part of cavity 121 of redistribution structure 120. The location of cavity 121 can correspond to (e.g., vertically overlap) the singulation streets between adjacent electronic components 110. In some examples, the width of cavity 121 can range from approximately 10 μm to approximately 300 μm. In some examples, the thickness of conductive structure 122 can range from approximately 2 μm to approximately 60 μm. In some examples, the thickness of dielectric structure 123 can range from approximately 2 μm to approximately 60 μm. In some examples, the thickness of redistribution structure 120 can range from approximately 2 μm to approximately 600 μm. It is understood that redistribution structure 120 can comprise more layers of dielectric and conductive structures than shown in FIG. 2E.

In some examples, redistribution structure 120 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this disclosure can also comprise an RDL substrate.

FIG. 2F shows a cross-sectional view of electronic device 100 at a later stage of manufacture. In the example shown in FIG. 2F, external interconnects 130 can be provided on the upper side of outward terminals 126.

External interconnects 130 can be in contact with and be electrically connected to outward terminals 126. External interconnects 130 can be electrically connected to bond pads 115 of electronic component 110 through conductive structure 122 of redistribution structure 120. In some examples, external interconnects 130 can comprise tin (Sn), silver (Ag), lead (Pb), Cu, Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 130 can be provided by providing a solder-containing conductive material to outward terminals 126 through a ball drop method and then through a reflow process. In some examples, external interconnects 130 can comprise or be referred to as solder balls, bumps, pads, pillars, or posts. In some examples, the thickness of external interconnects 130 can range from approximately 10 μm to approximately 400 μm.

FIG. 2G shows a cross-sectional view of electronic device 100 at a later stage of manufacture. In the example shown in FIG. 2G, component cavities 111 can be provided through portions 110AA of first side 110A, which are exposed from cavities 121. Component cavities 111 extend in downward or inward direction from first side 110A into electronic components 110. In some examples, component cavities 111 are substantially centered within cavities 121 and are spaced apart from redistribution structure 120 leaving part of portions 110AA in place as edge regions 110AA′. In the present example, sidewalls of component cavities 111 are not coplanar with sidewalls of redistribution structure 120 that define cavities 121. Edge regions 110AA′ can also comprise or be referred to as steps, upper edge regions, corners, or upper corner regions.

In some examples, component cavities 111 comprise a width that defines singulations lines for separating electronic components 110 into individual electronic components. In the present example, the width of component cavities 111 can be smaller than the width of cavity 121 of redistribution structure 120 to define edge regions 110AA′. in the present example, the width of components cavities 111 is greater than the width needed for the process elected to singulate electronic components 110 into individual electronic components. In some examples, the width of component cavities 111 can range from approximately 10 μm to approximately 300 μm.

In some examples, component cavities 111 can be provided by removing electronic component 110 to a certain depth through etching. In some examples, dry etching techniques can be used with a fluorine-based chemistry when electronic components 110 comprise Si. In some examples, the depth of the component cavities 111 can be approximately half the thickness of the electronic components 110 and can range from approximately 25 μm to approximately 775 μm. In some examples, second side 110B′ of electronic components 110, which is opposite to first side 110A, can comprise a generally planar topography.

FIG. 2H shows a cross-sectional view of electronic device 100 at a later stage of manufacture. In the example shown in FIG. 2H, protection layer 140 can be provided to fill component cavities 111 of electronic components 110 and cavities 121 of redistribution structure 120. Protection layer 140 can also comprise or be referred to as a protection structure.

In the present example, protection layer 140 substantially fills component cavities 111. In some examples, protection layer 140 completely fills component cavities 111 so that protection layer 140 contains no gaps or voids within component cavities 111. In some examples, protection layer 140 substantially fills cavities 121 and contacts (which can include direct contact) sidewalls of passivation layer 114 and sidewalls of redistribution structure 120. In the present example, protection layer 140 covers, adjoins, and contacts (which can include direct contact) edge regions 110AA′ of electronic components 110. This includes edge regions and corner regions proximate to where first side 110A and lateral side 110C meet. In some examples, the upper side of protection layer 140 can be coplanar with the upper side of redistribution structure 120 so that the upper side of redistribution structure 120 is devoid of protection layer 140. In some examples, protection layer 140 can be provided in a square or rectangular ring shape in a top plan view. Protection layer 140 can surround redistribution structure 120 in the top plan view. In some examples, protection layer 140 can comprise an epoxy mold compound (EMC), an epoxy resin, a filler-reinforced polymer, a B-stage press film, gel, a film, or combinations thereof. In some examples, protection layer 140 can be formed by Ink jetting or dispensing. In accordance with the present description, protection layer 140 is configured to protect first side 110A (including edge regions 110AA′) of electronic components 110, sidewalls of component cavities 111, the edges including corner edges between edge regions 110AA′ and sidewalls of components cavities 111, the sidewalls of passivation layer 114, and the sidewalls of redistribution structure 120. The sidewalls of redistribution structure 120 can be examples of first sidewalls and the sidewalls of passivation layer 114 can be examples of second sidewalls.

FIG. 2I shows a cross-sectional view of electronic device 100 at a later stage of manufacture. In the example shown in FIG. 2I, a portion of second side 110B′ (FIG. 2H) of electronic components 110 is removed to define second side 110B and to expose protection layer 140 from second side 110B.

In some examples, grinding or chemical mechanical planarization can be used to form second side 110B of electronic components 110. In some examples, after the planarization process, second side 110B of electronic components 110 and the lower side of protection layer 140 can be coplanar. In some examples, the overall thickness of electronic components 110 can range from approximately 25 μm to approximately 775 μm and the area (or “footprint”) of electronic components 110 can range from approximately 3 millimeters (mm)×3 mm to approximately 30 mm×30 mm. In the present example, lateral sides 110C of electronic components 110 can be covered and surrounded by protection layer 140.

After electronic components 110 are planarized in wafer form, a singulation process can be used to singulate the wafer to provide individual electronic devices 100. In the present example, the singulation is done through protection layer 140 while maintaining portions of protection layer intact along the sidewalls of redistribution structure 120 and lateral sides 110C of electronic components 110. In this way, protection layer 140 comprises a singulated layer where its outer side is formed by the singulation process. In some examples, the singulation process can utilize a diamond saw blade or a laser beam to singulation through protection layer 140. In some examples, the singulation is done with reference to a vertically oriented plane at the center of protection layer 140. Electronic device 100 can be separated into individual electronic elements by sawing protection layer 140. The presence of protection layer 140 can reduce or prevent chipping or microcracks when singulating electronic components 110.

In the present example, lateral sides 110C of electronic components 110 and the sidewalls of redistribution structures 120 are covered by protection layer 140. In addition, protection layer 140 comprises a first thickness T1 (i.e., in a lateral direction) adjacent to lateral sides 110C of electronic component 110 and a second thickness T2 (i.e., in a lateral direction) adjacent to the sidewalls of redistribution structure 120, which is greater than first thickness T1. In electronic device 100, stress can be concentrated more at the corner areas of the active side of electronic component 110, and thus chipping or microcracks can occur at a higher rate than in other areas. As the size of electronic component 110 decreases, the degree of stress on the active side can greatly affect the characteristics of electronic device 100. In protection layer 140 of electronic device 100, the second thickness T2 where the corner areas of the active side of electronic component 110 are covered can be greater than the first thickness T1 along laterals sides 110C of electronic component 110 are covered, thereby relieving the stress applied to the corner areas of the active side. This improves the robustness of electronic device 100 and improves yields, quality, and reliability.

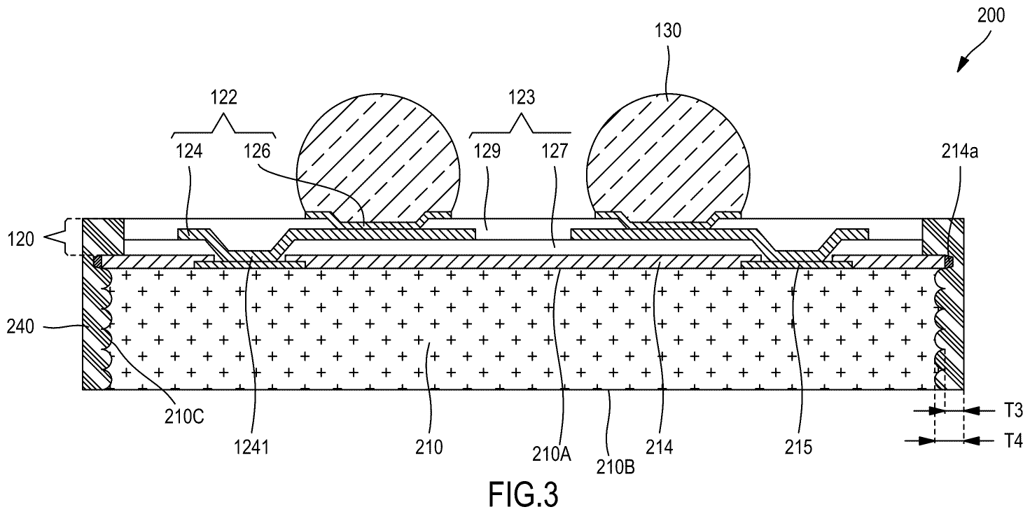

FIG. 3 shows a cross-sectional view of an example electronic device 200. In the example shown in FIG. 3, electronic device 200 can comprise electronic component 210, redistribution structure 120, external interconnects 130, and protection layer 240. Electronic device 200 is an example of a WLCSP.

Electronic component 210 can comprise a first side 210A, a second side 210B opposite to first side 210A, and a lateral side connecting first side 210A to second side 210B, and passivation layer 214 and bond pads 215 adjacent to first side 210A. Redistribution structure 120 can have corresponding elements similar to those of redistribution structure 120 of electronic device 100.

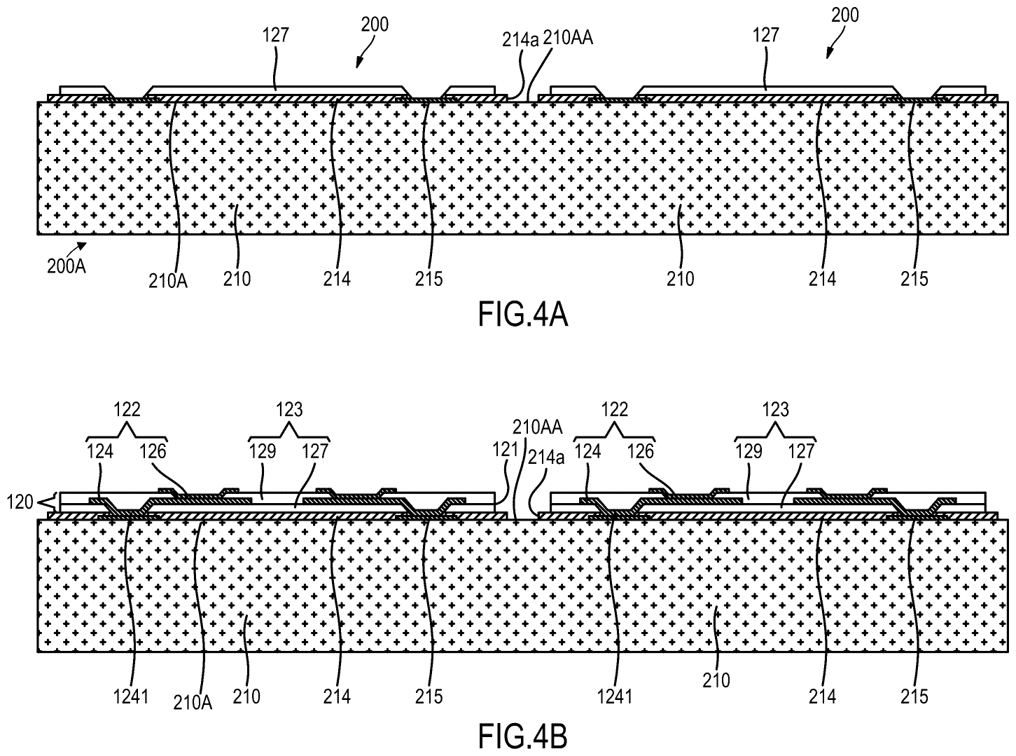

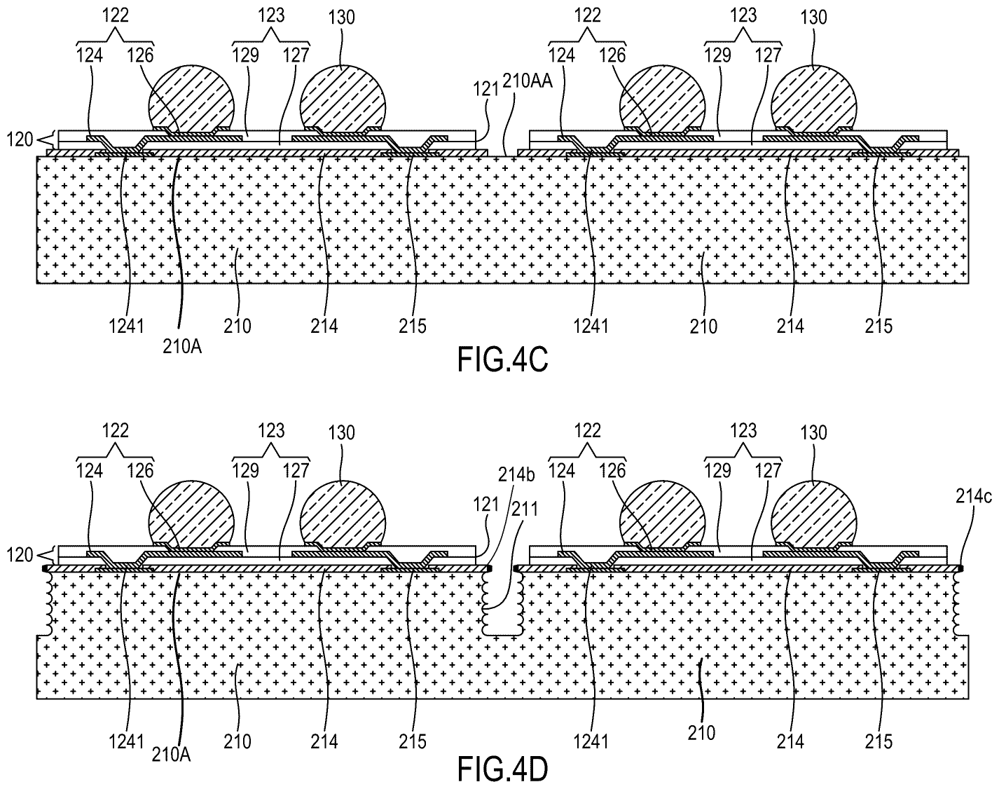

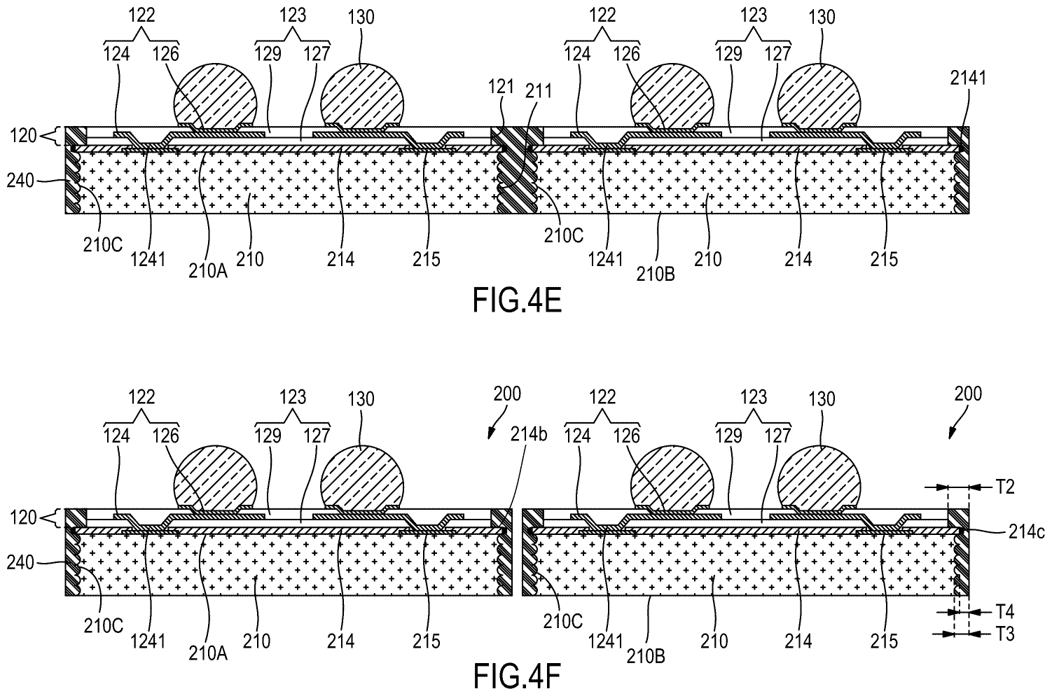

FIGS. 4A, 4B, 4C, 4D, 4E, and 4F show cross-sectional views of an example method for manufacturing an electronic device, such as electronic device 200.

FIG. 4A shows a cross-sectional view of electronic device 200 at an early stage of manufacture. In the example shown in FIG. 4A, inner dielectric material 127 can be provided to cover passivation layer 214 of electronic component 210. In the example shown in FIG. 4A, electronic device 200 can be provided in wafer form including a plurality of electronic devices 200 each comprising one of electronic components 210. In some examples, a plurality of electronic components 210 are provided within or as part of a semiconductor substrate 200A and additional features or elements are provided or added to the plurality of electronic components 210 before separating semiconductor substrate 200A into individual electronic devices 200. Semiconductor substrate 100A comprises a top side, which defines first sides 210A of electronic components 210 and a lower side opposite to the top side. Semiconductor substrate 200A can also comprise or be referred to as a semiconductor wafer or work piece.

Electronic components 210 can comprise bond pads 215 and passivation layer 214 provided adjacent to first side 210A. Electronic components 210 can have elements, features, materials, or manufacturing methods that are similar to, or the same as those of, electronic components 110 of electronic device 100 shown in FIG. 2A. Inner dielectric material 127 can be provided to cover passivation layer 214 of electronic component 210. Inner dielectric material 127 can have corresponding elements, features, materials, or manufacturing methods similar to those of inner dielectric material 127 of electronic device 100 shown in FIG. 2B.

In electronic components 210, the location of cavity 214a can correspond to (e.g., vertically overlap) singulations streets between adjacent electronic components 110. In the present example, the width of cavity 214a, which exposes portion 210AA of first side 210A, is smaller than the width of cavity 121 defined by redistribution structure 120 (see FIG. 4B). In the present example, this width difference exposes portions of the upper side or an edge area of passivation layer 214 proximate to portion 210AA of first side 210A. In this way, the sidewalls of passivation layer 214 can protrude laterally past the sidewalls of inner dielectric material 127 to provide a step between dielectric material 127 and passivation layer 214 proximate to portion 210AA. In some examples, the width of cavity 121 can range from approximately 10 μm to approximately 300 μm and the width of cavity 214a can be approximately 1% to approximately 99% of the width of cavity 121. In some examples, the width of cavity 214a can be approximately 40% to approximately 90% of the width of 121. In some examples, the width of cavity 214a can be approximately 50% to approximately 80% of the width of 121.

FIG. 4B shows a cross-sectional view of electronic device 200 at a later stage of manufacture. In the example shown in FIG. 4B, inner conductive pattern 124, outer dielectric material 129, and outward terminals 126 can be sequentially provided to cover inner dielectric material 127 and bond pads 215.

Inner conductive pattern 124, outer dielectric material 129, and outward terminals 126 can have corresponding elements, features, materials, or manufacturing methods similar to those of inner conductive pattern 124, outer dielectric material 129, and outward terminals 126 of electronic device 100 shown in FIGS. 2C to 2E.

After outward terminals 126 are provided, redistribution structure 120 can be completed. Redistribution structure 120 can comprise dielectric structure 123 and conductive structure 122. Dielectric structure 123 can comprise outer dielectric material 129 and inner dielectric material 127. Conductive structure 122 can comprise inner conductive pattern 124 and outward terminals 126. Conductive structure 122 and dielectric structure 123 can have corresponding elements, features, materials, or manufacturing methods similar to those of conductive structure 122 and dielectric structure 123 of electronic device 100.

Redistribution structure 120 can be located above passivation layer 214. The sidewalls of passivation layer 214 can protrude outward from the sidewalls of redistribution structure 120. Redistribution structure 120 of one electronic component 210 can be spaced apart from an adjacent redistribution structure 120 of another electronic components 210 by cavity 121 provided extending from the upper side of redistribution structure 120 to first side 210A of electronic components 210. Cavity 114a of passivation layer 114 can be part of cavity 121 of redistribution structure 120. As described previously, in the present example the sidewalls of passivation layer 114 can protrude toward the inside of cavity 121 than the sidewalls of redistribution structure 120, and thus a step can be provided in cavity 121.

In some examples, the thickness of conductive structure 122 can range from approximately 2 μm to approximately 60 μm. In some examples, the thickness of dielectric structure 123 can range from approximately 2 μm to approximately 60 μm. In some examples, the thickness of redistribution structure 120 can range from approximately 2 μm to approximately 600 μm. It is understood that redistribution structure 120 can comprise more layers of dielectric and conductive structures than shown in FIG. 4B.

FIG. 4C shows a cross-sectional view of electronic device 200 at a later stage of manufacture. In the example shown in FIG. 4C, external interconnects 130 can be provided on the upper side of outward terminals 126. External interconnects 130 can have corresponding elements, features, materials, or manufacturing methods similar to those of external interconnects 130 of electronic device 100 shown in FIG. 2F.

FIG. 4D shows a cross-sectional view of electronic device 200 at a later stage of manufacture. In the example shown in FIG. 4D, component cavities 211 can be provided through portions 210AA of first side 210A, which are exposed from cavities 121. Component cavities 211 extend in a downward or inward direction from first side 210A into electronic components 210. In some examples, a groove-shaped guideline is first provided in a downward direction from portions 210AA of first side 210A by irradiating a laser through laser grooving equipment. Next, component cavities 211 can be provided through using a plasma etching process in a downward direction from first side 210A of electronic components 210 by using passivation layer 214 as a mask and a selective etch chemistry that etches electronic components 210 at a faster rate than passivation layer 214. In the present examples, edge areas 214b of passivation layer 214 can protrude partially over component cavities 211. In this way edge areas 214b extend laterally outward to overlap and extend beyond lateral sides 210C of electronic components 210. Component cavity 211 can be provided by plasma etching, and thus the sidewalls of component cavity 211 can be scalloped. In some examples, the width of component cavity 211 can be smaller than the width of cavity 121 of redistribution structure 120. The width and depth of component cavity 211 can be similar to component cavity 111 shown in FIG. 2G.

Edge areas 214b of passivation layer 214 can comprise or be referred to as heat affected zone (HAZ) 214c, which can correspond to an edge area portion altered or deformed by heat provided during laser grooving processing. In the present example, heat affected zone 214c can be a portion of edge areas 214b protruding laterally outward compared to electronic component 210 and redistribution structure 120 toward or partially over component cavity 211. The width of heat affected zone 214c protruding compared to component cavity 211 can range from approximately 0.1 μm to approximately 2 μm. In some examples, the thickness of heat affected zone 214c can be equal to or smaller than the thickness of passivation layer 214. For example, the thickness of heat affected zone 214c can range from approximately 0.05 μm to approximately 10 μm.

FIG. 4E shows a cross-sectional view of electronic device 200 at a later stage of manufacture. In the example shown in FIG. 4E, protection layer 240 can be provided to fill component cavity 211 of electronic component 210 and cavity 121 of redistribution structure 120. Protection layer 240 can also comprise or be referred to as a protection structure.

In the present example, protection layer 240 substantially fills component cavities 211. In some examples, protection layer 240 completely fills component cavities 211 so that protection layer 240 contains no gaps or voids within component cavities 211. In some examples, protection layer 240 substantially fills cavities 121 and contacts sidewalls of redistribution structure 120. In the present example, protection layer 240 covers, adjoins, and contacts (which can include direct contact) the upper and lower sides of edge area 214b and the upper and lower sides and sidewall of heat affected zone 214c of passivation layer 114 and covers, adjoins, and contacts (which can include direct contact) lateral sides 210C of electronic components 210. In some examples, edge areas 214b are embedded within protection layer 240. In some examples, the upper side of protection layer 240 can be coplanar with the upper side of redistribution structure 120. In some examples, the upper side of redistribution structure 120 is devoid of protection layer 240. Protection layer 240 can have corresponding elements, features, materials, or manufacturing methods similar to those of protection layer 140 of electronic device 100 shown in FIG. 2H.

FIG. 4F shows a cross-sectional view of electronic device 200 at a later stage of manufacture. In the example shown in FIG. 4F, a portion of the lower side of electronic components 210 is removed to define second side 210B of electronic components 210 and to expose protection layer 240 from second side 210B.

In some examples, grinding or chemical mechanical planarization can be used to form second side 210B of electronic components 210. In some examples, after the planarization process, second side 210B of electronic components 210 and the lower side of protection layer 240 can be coplanar. After electronic components 210 are planarized in wafer form, a singulation process can be used to singulate the wafer to provide individual electronic devices 200. The planarization and singulation processes can be similar to the planarization and singulation processes of electronic device 100 shown in FIG. 2I, respectively.

In the present example, lateral sides 210C of electronic components 210, edge areas 214b (including heat affected zones 214c), and the sidewalls of redistribution structure 120 are covered by protection layer 240. In some examples, edge areas 214b (including heat affected zones 214c) are embedded within protection layer 240 so that a top side, a bottom side, and a lateral side of edge areas 214b (including heat affected zones 214c) are covered by protection layer 240. In addition, protection layer 240 comprises thickness T2 adjacent to redistribution structure 120 and thickness T3 and T4 adjacent to lateral sides 210C of electronic components 210. In the present example, thickness T2 is greater than thicknesses T3 and T4. In this way, the thickness of protection layer 240, where the edge and corner areas of the active side of electronic components 210 are covered is greater than the thickness adjacent to lateral sides 210C of electronic component 210 are covered, thereby relieving the stress applied to the corner areas of the active side of electronic component 210. Since the side walls of component cavity 211 of electronic component 210 are scalloped, the contact area with protection layer 240 can be increased, and the stress can be further reduced. This improves the robustness of electronic device 200 and improves yield, quality, and reliability.

In the present example, protection layer 240 comprises third thickness T3 where protection layer 240 fills scalloped concave portions of component cavity 211. In some examples, third thickness T3 can range from approximately 1.1 μm to approximately 50.1 μm. In addition, protection layer 240 comprises fourth thickness T4 where protection layer 240 covers the scalloped protruding part or convex portions of component cavity 211. In some examples, fourth thickness T4 can range from approximately 1 μm to approximately 50 μm. Third thickness T3 is an example of a first thickness first portion and fourth thickness T4 is an example of a first thickness second portion where the first thickness first portion is thicker than the first thickness second portion.

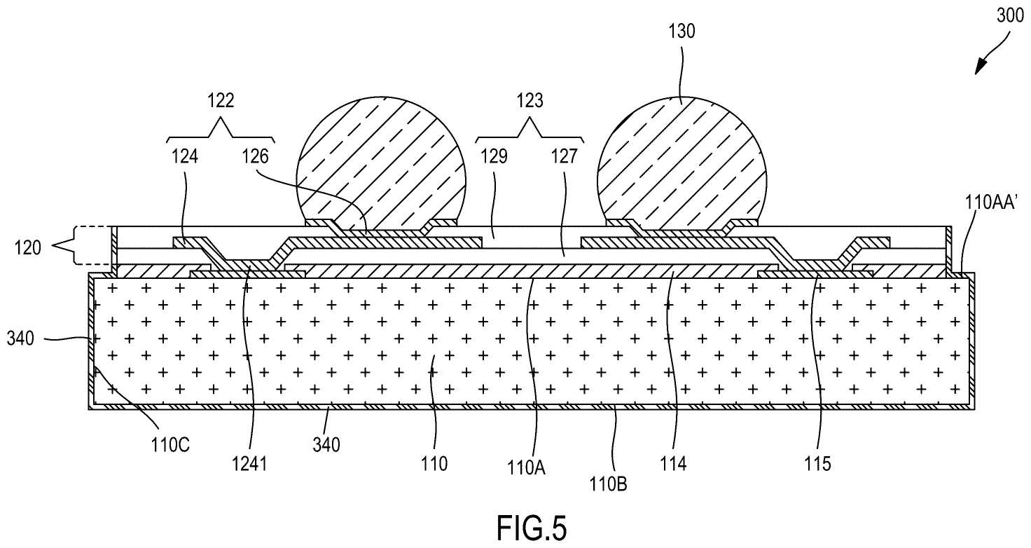

FIG. 5 shows a cross-sectional view of an example electronic device 300. In the example shown in FIG. 5, electronic device 300 can comprise electronic component 110, redistribution structure 120, external interconnects 130, and protection layer 340. Electronic device 300 is an example of a WLCSP.

Electronic component 110 and redistribution structure 120 of electronic device 300 can have corresponding elements similar to those of electronic component 110, redistribution structure 120, and external interconnects 130 of electronic device 100.

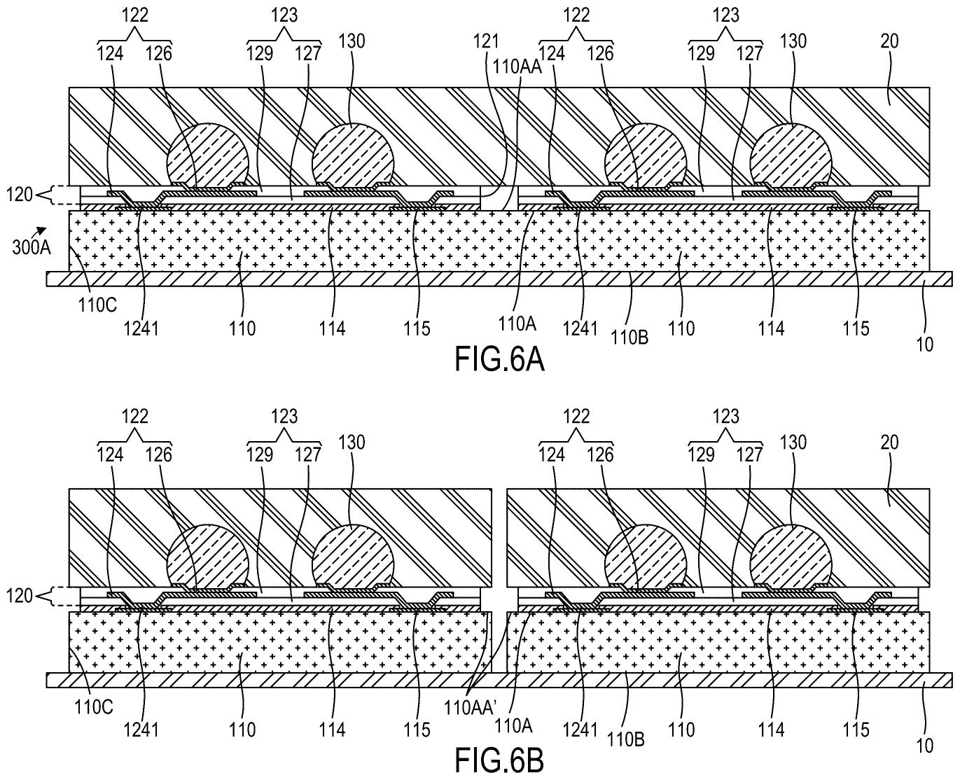

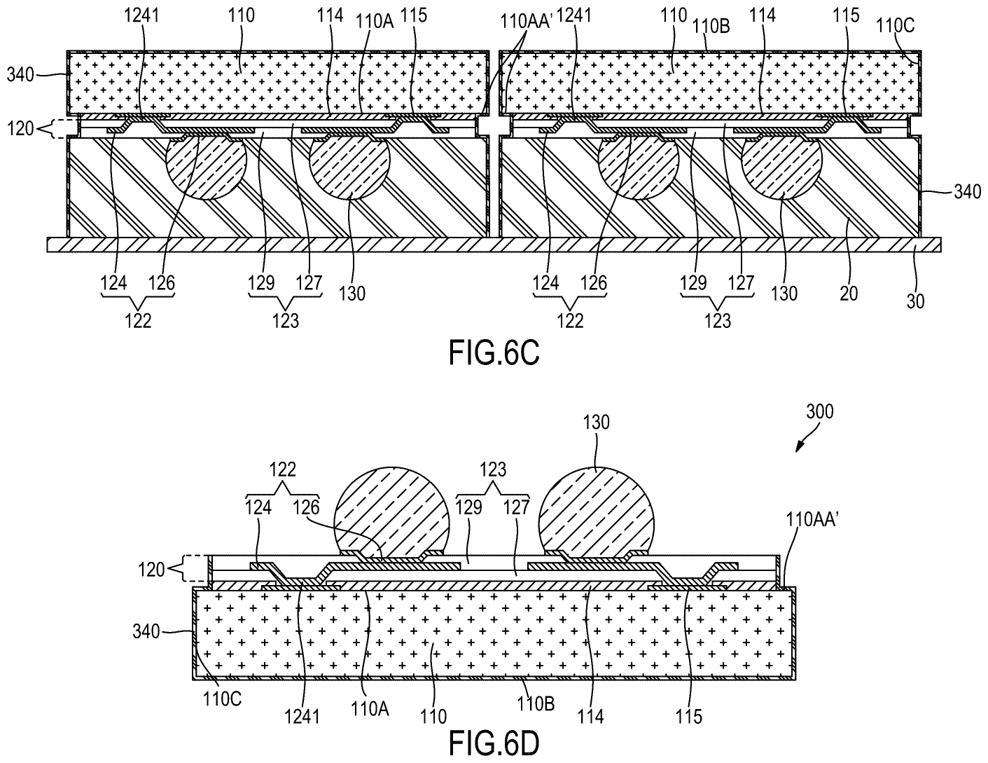

FIG. 6A shows a cross-sectional view of electronic device 300 at an early stage of manufacture. In the present example, electronic device 300 can be provided in wafer form including a plurality of electronic devices 300 each including one of electronic components 110. In some examples, a plurality of electronic components 110 are provided within or as part of a semiconductor substrate or wafer 300A and additional features or elements are provided or added to the plurality of electronic components 110 before separating the semiconductor substrate into individual electronic devices 300. In some examples, second sides 110B of electronic components 110 can be attached to carrier 10, and protective structure 20 can be attached to cover redistribution structure 120 and external interconnects 130. In some examples, protective structure 20 comprises a tape or film, such as a back grinding tape. In some examples, electronic device 300 can have a redistribution structure 120 provided over first sides 110A of electronic components 110 through the manufacturing process shown in FIGS. 2A to 2F.

In some examples, carrier 10 can comprise a substantially planar plate. In some examples, carrier 10 can comprise or be referred to as a plate, a board, a wafer, a panel, or a strip. For example, carrier 10 can be provided as a wafer or a dicing (sawing) tape. In some examples, the thickness of carrier 10 can range from approximately 50 μm to approximately 2000 μm, and the width of carrier 10 can range from approximately 100 mm to approximately 500 mm. Carrier 10 can serve to handle electronic devices 300 as a single body after the singulation process. In some examples, carrier 10 can be attached to a frame structure for additional support.

Carrier 10 can comprise a temporary bond layer provided on the upper side. The upper side of the temporary adhesive layer of carrier 10 can be in contact with and be fixed to second sides 110B of electronic components 110. The temporary bond layer can be provided on the upper side of carrier 10 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape. In some examples, the temporary bond layer can comprise or be referred to as a temporary bonding film, a temporary bonding tape or a temporary adhesive coating. For example, the temporary bonding layer can be a heat release tape (film) or an optical release tape (film). In some examples, the adhesive strength of the temporary bond layer can be weakened or removed by physical and/or chemical external force. The temporary bond layer can allow carrier 10 to be separated from electronic components 110 when the singulation process is completed. Carrier 10 is an example of a first carrier.

In some examples, protection structure 20 can comprise a back grinding tape and can be hardened by ultraviolet rays and attached to cover the upper side of redistribution structure 120 and the outer surfaces of external interconnects 130. in the present example, protection structure 20 does not fill cavity 121 of redistribution structure 120 or cover portions 110AA of first side 110A of electronic components 110. In this way, cavity 121 of redistribution structure 120 comprises a void, gap, or empty space that is devoid of protection structure 20. Protection structure 20 can comprise or be referred to as a non-conductive material, protective tape, or an adhesive film. Protection structure 20 can prevent redistribution structure 120 and external interconnects 130 from being damaged by residues generated during the singulation process. In some examples, protection structure 20 can be polyimide (PI) or polyethylene terephthalate (PET). In some examples, the thickness of protection structure 20 can range from approximately 50 μm to approximately 1000 μm, and the width of protection structure 20 can range from approximately 100 mm to approximately 500 mm. In the present example, the location of cavity 121 can correspond to (e.g., vertically overlap) singulations streets between adjacent electronic components 110.

FIG. 6B shows a cross-sectional view of electronic device 300 at a later stage of manufacture. In the example shown in FIG. 6B, a singulation process can be performed to separate protection structure 20 and electronic components 110 into individual electronic devices 300 by sawing.

In some examples, portions of protection structure 20 and electronic component 110 located above and below cavity 121 respectively can be removed by sawing. In the present example, lateral sides 110C of electronic components 110 sidewalls of electronic component 110 extend outward with respect to compared to the sidewalls of redistribution structure 120 and passivate layer 114 to provide edge regions 110AA′. In this way, the edge areas of electronic components 110 can be exposed on first sides 110A. In the present example, the width of cavity 121 between adjacent redistribution structures 120 is greater than the widths of gaps between adjacent portions of singulated protection structure 20 and adjacent portions of lateral sides 110C of singulated electronic components 110. The singulation process can be similar to the singulation process for electronic device 100 shown in FIG. 2I.

FIG. 6C shows a cross-sectional view of electronic device 300 at a later stage of manufacture. In the example shown in FIG. 6C, protection layer 340 can be provided to cover electronic components 110, redistribution structures 120, and protection structure 20.

Before protection layer 340 is provided, carrier 30 can be attached to cover the upper side of protection structure 20 and carrier 10 can then be removed to expose second sides 110B of electronic components 110. Carrier 30 can have corresponding elements, features, materials, or manufacturing methods similar to those of carrier 10 described previously. After carrier 10 is removed, electronic device 300 can be flipped, so second sides 110B of electronic components 110 are oriented in an upward direction and the upper sides of protection structures 20 are oriented in a downward direction.

In the present example, protection layer 340 can be in contact with upper sides 110A (e.g., edge regions 110AA′), lateral sides 110C, and second sides 110B of electronic components 110. In addition, protection layer 340 is in contact with the sidewall of passivate layer 114, the sidewalls of redistribution structure 120 and the sidewalls of protection structure 20. In some examples, protection layer 340 can comprise a ceramic, metal, SiOx, SiN, an insulating material, or combinations thereof. Protection layer 340 can be provided by deposition. In some examples, protection layer 340 can be provided using ALD.

FIG. 6D shows a cross-sectional view of electronic device 300 at a later stage of manufacture. In the present example, protection structure and carrier 30 are removed from redistribution structure 120 and external interconnects 130. In some examples, protection structure 20 and carrier 30 can be removed by chemical means, pulling, peeling, or combinations thereof. Electronic device 300 can then be flipped so electronic component 110 is reoriented in a downward direction and redistribution structure 120 and external interconnects 130 are reoriented in an upward direction for further processing.

In the present example, protection layer 340 contacts (which can include direct contact) contacts second side 110B and lateral side 110C of electronic component 110. In addition, protection layer 340 can contact (which can include direct contact) edge regions 110AA′ or exposed portions of first side 110A of electronic component 110, which are not covered by passivation layer 140 or redistribution structure 120. This includes edge regions and corner regions proximate to where first side 110A and lateral side 110C meet. In some examples, protection layer 340 contacts (which can include direct contact) the sidewalls of redistribution structure 120. In some examples, the upper side of redistribution structure 20 is devoid of protection layer 340. Protection layer 340 can protect electronic component 110 and redistribution structure 120 from external shock and moisture. Protection layer 340 can be provided to cover not only the side walls of electronic component 110 but also the lower side, thereby facilitating protection of electronic component 110. In some examples, the thickness of protection layer 340 can range from approximately 0.01 μm to approximately 1 μm.

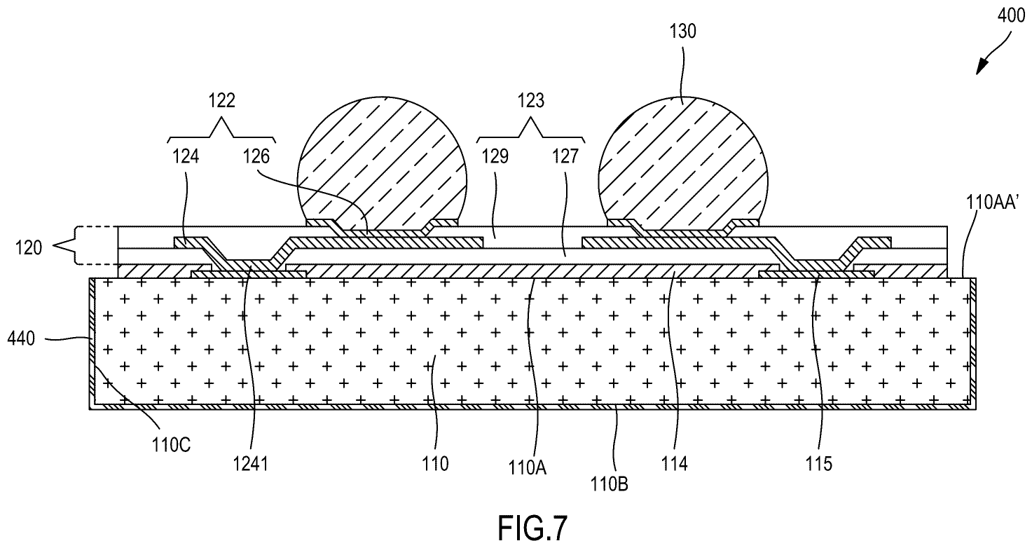

FIG. 7 shows a cross-sectional view of an example electronic device 400. In the example shown in FIG. 7, electronic device 400 can comprise electronic component 110, redistribution structure 120, external interconnects 130, and protection layer 440. Electronic device 300 is an example of a WLCSP.

Electronic component 110 and redistribution structure 120 can have corresponding elements similar to electronic component 110 and redistribution structure 120 of electronic devices 100 and 300. In the present example, edge regions 110AA′ and the sidewalls of passivate layer 114, the sidewalls of redistribution structure 120, and the upper side of redistribution structure 120 are devoid of protection layer 440.

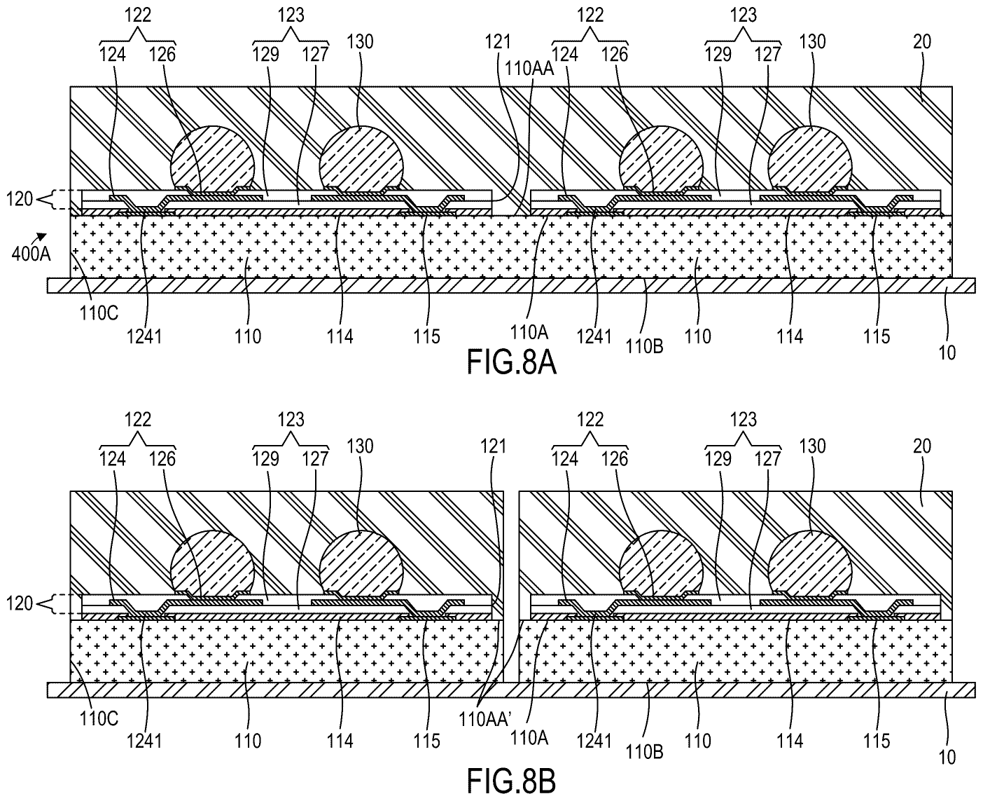

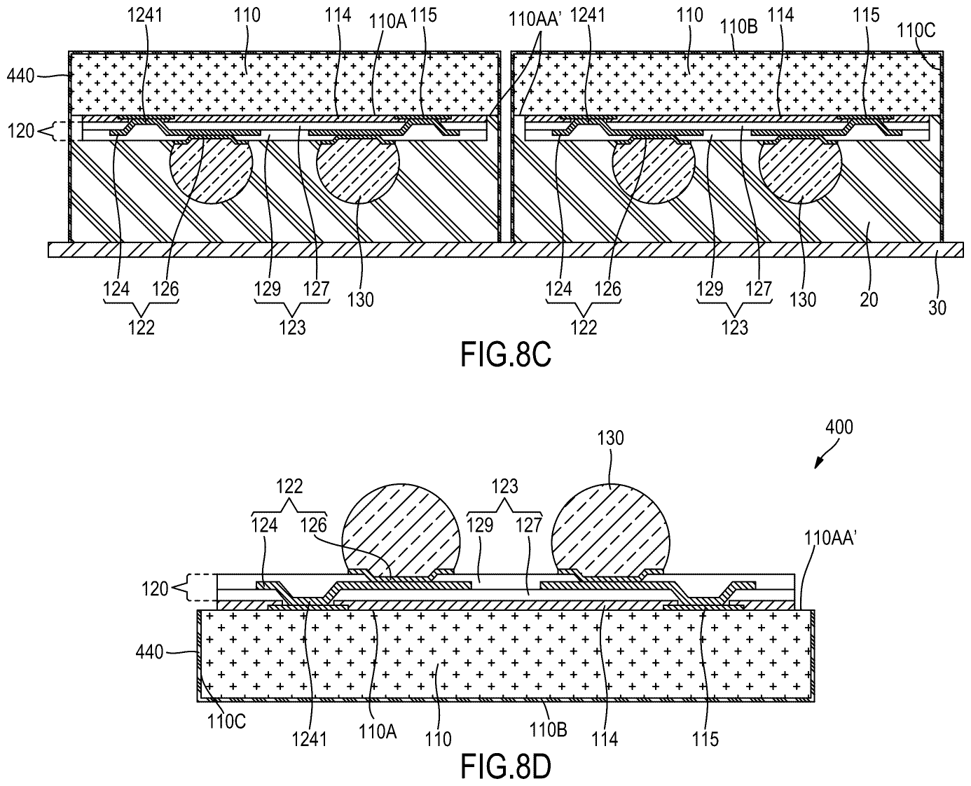

FIG. 8A shows a cross-sectional view of electronic device 400 at an early stage of manufacture. In the present example, electronic device 400 can be provided in wafer form including a plurality of electronic devices 400 each including one of electronic components 110. In some examples, a plurality of electronic components 110 are provided within or as part of a semiconductor substrate 400A and additional features or elements are provided or added to the plurality of electronic components 110 before separating semiconductor substrate 400A into individual electronic devices 400. Semiconductor substrate 400A comprises a top side, which defines first sides 110A of electronic components 110 and a lower side opposite to the top side. Semiconductor substrate 400A can also comprise or be referred to as a semiconductor wafer or work piece. In the example shown in FIG. 8A, second sides 110B of electronic components 110 can be attached to carrier 10, and protection structure 20 can be attached to cover redistribution structure 120 and external interconnects 130.

In some examples, electronic devices 400 can comprise redistribution structures provided over first sides 110A of electronic components 110 by the manufacturing process shown in FIGS. 2A to 2F. In some examples, carrier 10 and protection structure 20 can have corresponding elements, features, materials, or manufacturing methods similar to those of carrier 10 and protection structure 20 described previously with electronic device 300 as shown in FIG. 6A.

In the present example, protection structure 20 can be in contact with the upper surface and side walls of redistribution structure 120, the sidewalls of passivate layer 114, and external interconnects 130. In the present example, protection structure 20 can also be in contact with portions 110AA of first sides 110A of electronic components 110. In the present example, protection structure 20 completely fills cavity 121 of redistribution structures 120. In the present example, the location of cavity 121 can correspond to (e.g., vertically overlap) singulations streets between adjacent electronic components 110.

FIG. 8B shows a cross-sectional view of electronic device 400 at a later stage of manufacture. In the example shown in FIG. 8B, a singulation process can be performed to separate protection structure 20 and electronic components 110 into individual electronic devices 400 by sawing.

In the singulation process, portions of protective structure 20 and electronic components 110 can be separated. In the present example, the side walls of redistribution structure 120, the sidewalls of passivate layer 114, and portions 110AA of first sides 110A can be covered by protection structure 20 during the singulation process. In some examples, the side walls of protection structure 20 and lateral sides 110C of electronic components 110 can be coplanar with each other. The singulation process can be similar to the singulation process of electronic device 100 shown in FIG. 2I.

FIG. 8C shows a cross-sectional view of electronic device 400 at a later stage of manufacture. In the example shown in FIG. 8C, protection layer 440 can be provided to cover electronic components 110 and protection structure 20.

Before protection layer 440 is provided, carrier 30 can be attached to cover the upper side of protection structure 20 and carrier 10 can then be removed to expose second sides 110C of electronic components 110. Carrier 30 can have corresponding elements, features, materials, or manufacturing methods similar to those of carrier 10. After carrier 10 is removed, electronic device 400 can be flipped, so second sides 110B of electronic components 110 are oriented in an upward direction and the upper sides of protection structures 20 are oriented in a downward direction. Carrier 30 is an example of a second carrier.

Protection layer 440 can have corresponding elements, features, materials, or manufacturing methods similar to those of protection layer 340 of electronic device 300. In some examples, protection layer 440 is provided using ALD processing techniques. In the present example, protection layer 440 can be in contact (which can include direct contact) with sidewalls of protection structure 20 and second sides 110B and lateral sides 110C of electronic components.

FIG. 8D shows a cross-sectional view of electronic device 400 at a later stage of manufacture. In the present example, protection structure and carrier 30 are removed from redistribution structure 120 and external interconnects 130. In some examples, protection structure 20 and carrier 30 can be removed by chemical means, pulling, peeling, or combinations thereof. Electronic device 400 can then be flipped so electronic component 110 is reoriented in a downward direction and redistribution structure 120 and external interconnects 130 are reoriented in an upward direction for further processing.

In the present example, protection layer 440 contacts (which can include direct contact) contacts second side 110B and lateral side 110C of electronic component 110. In the present example, the sidewalls and the upper side of redistribution structure 20 and region regions 110AA′ of electronic component 110 are devoid of protection layer 440. Protection layer 440 can protect electronic component 110 from external shock and moisture. Protection layer 440 can be provided to cover not only the side walls of electronic component 110 but also the lower side, thereby facilitating protection of electronic component 110. In some examples, the thickness of protection layer 340 can range from approximately 0.01 μm to approximately 1 μm.

In summary, structures and methods that relate to protecting electronic devices have been described. In some examples, the structures and methods are useful for manufacturing WLCSP's. More particularly, structures and methods are described that use protectives structures to cover exposed portions of the electronic device that are exposed during manufacturing, such as edge regions, side regions, and corner regions. The structures and methods improve the reliability of electronic devices that reduce defects associated with manufacturing stress, such as chipping or micro cracks at edges of the electronic devices. It was found through experimentation that the protective structures as described herein reduce the occurrence of micro-cracks, chipping and other defects thereby improving yield, quality, and reliability. In addition, it was found that the protective structures do not result in other defects, such as wafer warpage.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure are not limited to the examples disclosed, but that the disclosure will include all examples falling within the scope of the appended claims.

What is claimed is:

1. An electronic device, comprising:
an electronic component comprising:
a first side;
a second side opposite to the first side;
a lateral side connecting the first side to the second side;
bond pads adjacent to the first side; and
a passivation layer over the first side and comprising openings exposing the bond pads;
a redistribution structure over the passivation layer and the bond pads and comprising:
a conductive structure coupled to the bond pads and comprising outward terminals; and
a dielectric structure;
external interconnects coupled to the outward terminals; and
a protection layer covering the lateral side of the electronic component.

2. The electronic device of claim 1, wherein:
the redistribution structure comprises a sidewall;
the sidewall of the redistribution structure is inset from the lateral side of the electronic component to expose an edge portion of the electronic component at the first side; and
the protection layer comprises a first portion that covers the lateral side of the electronic component and a second portion that covers the edge portion of the electronic component and the sidewall of the redistribution structure.

3. The electronic device of claim 2, wherein:
the edge portion is devoid of the passivation layer so that the protection layer makes direct contact with the first side of the electronic component at the edge portion.

4. The electronic device of claim 2, wherein:
the first portion comprises a first thickness;
the second portion comprises a second thickness; and
the second thickness is greater than the first thickness.

5. The electronic device of claim 4, wherein:
the lateral side of the electronic component comprises a scalloped shape in a cross-sectional view comprising concave portions and convex portions;
the passivation layer comprises an edge area that extends laterally outward to overlap and extend beyond the lateral side of the electronic component;
the edge area is embedded within the protection layer;
the first thickness comprises a first thickness first portion adjacent to the concave portions;
the first thickness comprises a first thickness second portion adjacent to the convex portions; and
the first thickness first portion is thicker than the first thickness second portion.

6. The electronic device of claim 2, wherein:
the redistribution structure comprises an upper side; and
the second portion of the protection layer is coplanar with the upper side of the redistribution structure.

7. The electronic device of claim 1, wherein:
the electronic component comprises a semiconductor material;
the electronic device is configured as wafer-level chip scale package (WLCSP);
the redistribution structure comprises an upper side; and
the upper side of the redistribution structure and the external interconnects are devoid of the protection layer.

8. The electronic device of claim 1, wherein:
the protection layer comprises a singulated layer.

9. The electronic device of claim 1, wherein:
the redistribution structure comprises a first sidewall;
the passivation layer comprises a second sidewall;
the first sidewall and the second sidewall are inset from the lateral side of the electronic component to expose an edge portion of the electronic component at the first side; and
the protection layer comprises:
a first portion covering the lateral side of the electronic component; and
a second portion covering the second side of the electronic component.

10. The electronic device of claim 9, wherein:
the protection layer comprises a third portion covering the edge portion at the first side, the first sidewall, and the second sidewall.

11. An electronic device, comprising:
an electronic component comprising:
a first side;
a second side opposite to the first side;
a lateral side connecting the first side to the second side;
bond pads adjacent to the first side; and
a passivation layer over the first side and comprising openings exposing the bond pads;
a redistribution structure over the passivation layer and the bond pads and comprising:
a conductive structure coupled to the bond pads and comprising outward terminals;
a dielectric structure; and
a sidewall inset from the lateral side of the electronic component to expose an upper edge portion of the electronic component at the first side;
external interconnects coupled to the outward terminals; and
a protection layer covering the lateral side and the upper edge portion of the electronic component and the sidewall of the redistribution structure.

12. The electronic device of claim 11, wherein:
the protection layer comprises a first portion that covers the lateral side of the electronic component and a second portion that covers the upper edge portion of the electronic component and the sidewall of the redistribution structure;
the first portion comprises a first thickness;
the second portion comprises a second thickness;
the second thickness is greater than the first thickness; and
the protection layer is coplanar with an upper side of the redistribution structure.

13. A method of manufacturing an electronic device, comprising:
providing an electronic component comprising:
a first side;
a second side opposite to the first side;
a lateral side connecting the first side to the second side;
bond pads adjacent to the first side; and
a passivation layer over the first side and comprising openings exposing the bond pads;
providing a redistribution structure over the passivation layer and the bond pads and comprising:
a conductive structure coupled to the bond pads and comprising outward terminals; and
a dielectric structure;
providing external interconnects coupled to the outward terminals; and
providing a protection layer covering the lateral side of the electronic component.

14. The method of claim 13, wherein:
providing the redistribution structure comprises providing the redistribution structure with a sidewall inset from the lateral side of the electronic component to expose an upper edge portion of the electronic component at the first side;
providing the protection layer comprises providing a first portion that covers the lateral side of the electronic component and a second portion that covers the upper edge portion of the electronic component and the sidewall of the redistribution structure;
the first portion comprises a first thickness;
the second portion comprises a second thickness; and
the second thickness is greater than the first thickness.

15. The method of claim 14, wherein:
providing the electronic component comprises:
providing the lateral side with a scalloped shape in a cross-sectional view comprising concave portions and convex portions; and
providing the passivation layer with an edge area that extends laterally outward to overlap and extend beyond the lateral side of the electronic component;
providing the protection layer comprises embedding the edge area within the protection layer;
the first thickness comprises a first thickness first portion adjacent to the concave portions;
the first thickness comprises a first thickness second portion adjacent to the convex portions; and
the first thickness first portion is thicker than the first thickness second portion.

16. The method of claim 13, wherein:
providing the electronic component comprises providing the electronic component as part of a plurality of electronic components within a semiconductor substrate, the semiconductor substrate comprising a top side that defines first sides of each of the plurality of electronic components and a lower side opposite to the top side;
providing the redistribution structure comprises providing the redistribution structure as part of a plurality of redistribution structures, each of the plurality of redistribution structures over the first sides of each of the plurality of electronic components and separated by cavities that define singulation streets;
the method further comprises forming component cavities extending inward from the top side of the semiconductor substrate from the singulation streets;
providing the protection layer comprises filling the component cavities with the protection layer; and
the method further comprises:
removing a portion of the lower side of the semiconductor substrate to define second sides of each of the plurality of electronic components and to expose the protection layer from the second sides; and
singulating the semiconductor substrate through the protection layer to provide a plurality of individual electronic devices.

17. The method of claim 16, wherein:
providing the protection layer comprises:
providing the protection layer with a first thickness adjacent to the lateral side of the electronic component;
providing the protection layer with a second thickness adjacent to a sidewall of the redistribution structure and an upper edge portion of the electronic component; and
the second thickness is greater than the first thickness.

18. The method of claim 13, wherein:
providing the electronic component comprises providing the electronic component as part of a plurality of electronic components within a semiconductor substrate, the semiconductor substrate comprising a top side that defines first sides of each of the plurality of electronic components and a lower side opposite to the top side;
providing the redistribution structure comprises providing the redistribution structure as part of a plurality of redistribution structures, each of the plurality of redistribution structures over the first sides of each of the plurality of electronic components and separated by cavities that define singulation streets;
providing the external interconnects comprises providing the external interconnects coupled to each of the plurality of redistribution structures;
the method further comprises:
attaching the lower side of the semiconductor substrate to a first carrier;
attaching a protection structure to the external interconnects and the plurality of redistribution structures; and
singulating through the protection structure and the singulation streets to separate the semiconductor substrate into a plurality of individual electronic devices attached to the first carrier; and
after singulating:
providing the protection layer, wherein the protection layer covers sidewalls of the protection structure and lateral sides of each of the plurality of electronic components.

19. The method of claim 18, wherein:
attaching the protection structure comprises filling the cavities with the protection structure; and
after singulating:
attaching a second carrier to the protection structure;
removing the first carrier; and
after removing the first carrier providing the protection layer covering the sidewalls of the protection structure, lateral sides of each of the plurality of electronic components, and the lower side of the semiconductor substrate.

20. The method of claim 18, wherein:
attaching the protection structure comprises providing the cavities devoid of the protection structure; and
providing the protection layer comprises providing the protection layer covering sidewalls of each of the plurality of redistribution structures and upper edge portions of the plurality of electronic components.
